(19) United States
(12) Patent Application Publication
(10) Pub. No.: US 2012/0024671 A1
(43) Pub. Date: Feb. 2, 2012

(54) TRANSFERRING MECHANISM OF CONTACT TEST

(75) Inventors: Yi-chang YANG, Tu Cheng (TW); Kuo-chuan CHIU, Tu Cheng (TW); Feng-chi LEE, Tu Cheng (TW)

(73) Assignee: Cheng Uei Precision Industry Co., LTD., Tu Cheng City (TW)

(21) Appl. No.: 12/846,830

(22) Filed: Jul. 30, 2010

(51) Int. Cl. B65G 19/02; B65G 35/00; G01R 31/02

(52) U.S. Cl. 198/722; 324/537

(57) ABSTRACT

A transferring mechanism of contact test, applied to transfer a raw material band of terminals for a contact test of fan-shaped band of terminals is disclosed. The transferring mechanism of contact test comprises a main body, a driving shaft, a driving gear, a driven shaft, a driven gear and a transmission element. The transmission element connects to the driving shaft to rotate the driving shaft, the driving gear. The driving shaft rotates the driven shaft, the driven gear by a belt. The driving gear and the driven gear are ratchets. With the thorn teeth thereof matching with holes of the raw material band of terminals, a transferring mechanism with high speed transfer, exact location and simple structure during the transfer can be realized. Moreover, an arching of the raw material band of terminals can be prevented for guaranteeing the accuracy of the contact test.

### BACKGROUND OF THE INVENTION

1. Field of the Invention

The present invention generally relates to a transferring mechanism, and more particularly to a transferring mechanism of contact test for conductive terminals.

2. Description of Prior Art

With constant developments of electronic technology, connectors (adaptors) are widely used inside all kinds of electronic products, such as cellular phones, computers, MP3 players or their gadgets or peripherals for transferring signals or powers. A connector generally comprises a main body and a conductive terminal part. Nowadays, the conductive terminals are generally fabricated by direct stamping with a mold. In the stamping procedure, the internal stress of the original material for fabricating the terminals is easily released and leads the terminals to be bent broadwise. Such phenomenon is so called fan shaped band of terminals. To avoid the fan shaped band of terminals happening to the conductive terminals and the assembly and quality of the connector is consequently affected during the fabrication of the connector. There is a need to proceed a contact test for the conductive terminals before assembly of the connectors.

As shown in FIG. 1, in the contact test for conductive terminals according to prior art, a back-forth cylinder type transferring mechanism is generally utilized for transferring the raw material band of terminals 40. The back-forth cylinder type transferring mechanism in FIG. 1 comprises a base 10, a guide (not shown), a cylinder (not shown), a rotating shaft 12, a hook 14 and a pressing block 16. The guide is set up on the base 10. The cylinder is installed on the base 10. One end of the rotating shaft 12 is hinge jointed with the cylinder with a swing arm. The other end of the rotating shaft 12 is equipped with the hook 14. The lower side of the hook 14 has a tilt arm 141 like tool nose. The size of the tilt arm 141 should match with the holes 41 of the raw material band of terminals 40. The pressing block 16 is also installed on the base 10. The cylinder can drive the rotating shaft 12 to and fro to allow the hook 14 swing back and forth so to hook or unhook the raw material band of terminals 40.

Before the back-forth cylinder type transferring mechanism is activated, the hook 14 unhooks the raw material band of terminals 40 and the cylinder is at the leftmost pre-transfer position.

As the back-forth cylinder type transferring mechanism is activated, the cylinder drives the rotating shaft 12 rotated clockwise and the hook 14 is also driven clockwise to a level position. As the hook 14 is at the level position, the tilt arm 141 becomes to lock a hole 41 of the raw material band of terminals 40. Then, the cylinder moves to the right to transfer the raw material band of terminals 40 toward the right of the base 10. As the cylinder stops at the rightmost position, the tilt arm 141 of the hook 14 still locks the hole 41 of the raw material band of terminals 40 and the pressing block 16 remains pressing the raw material band of terminals 40.

Thereafter, the cylinder drives the rotating shaft 12 rotated counterclockwise and the tilt arm 141 of the hook 14 is driven and swings back to unlock the hole of the raw material band of terminals 40. And then, the cylinder drives the hook 14 back to the leftmost pre-transfer position. At this movement, the raw material band of terminals 40 stays still.

By repeating the foregoing procedures, a transfer of a raw material band of terminals 40 is completed.

However, the foregoing back-forth cylinder type transferring mechanism can easily causes an arching of the raw material band of terminals 40 because the cylinder moves left and right, back and forth constantly. The back-forth cylinder type transferring mechanism affects the accuracy of the contact test unavoidably and the structure of the back-forth cylinder type transferring mechanism is complex and transfer speed is too slow.

### SUMMARY OF THE INVENTION

For solving the drawbacks of prior art, a transferring mechanism of contact test with high speed transfer and simple structure which can effectively prevent an arching of the raw material band of terminals is provided.

The transferring mechanism of contact test of the present invention applied to transfer a raw material band of terminals for a contact test of fan-shaped band of terminals. The raw material band of terminals has holes arranged along the terminals correspondingly. The transferring mechanism of contact test comprises a long main body with two ends, a driving shaft, a driving gear connected with the driving shaft, a driven shaft, a driven gear connected with the driven shaft and a transmission element. The driving shaft and the driving gear are positioned at one end of the main body. The driven shaft and the driven gear are positioned at the other end of the main body. The transmission element connects to the driving shaft to rotate the driving shaft and the driving gear. The driving shaft rotates the driven shaft and the driven gear by a belt. The driving gear and the driven gear are ratchets. The thorn teeth of the driving gear and the driven gear match with the holes of the raw material band of terminals.

As aforementioned, the driving gear and the driven gear are ratchets and thorn teeth thereof match with the holes of the raw material band of terminals. With the aforesaid matching and the property of the ratchets during the transfer, the transfer speed can be high; the transfer location can be exact; and the transfer structure is simple. Moreover, an arching of the raw material band of terminals can be effectively prevented and therefore the accuracy of the contact test can be guaranteed.

### BRIEF DESCRIPTION OF THE DRAWINGS

FIG. 1 depicts a structure diagram of a back-forth cylinder type transferring mechanism with a raw material band of terminals according to prior art.

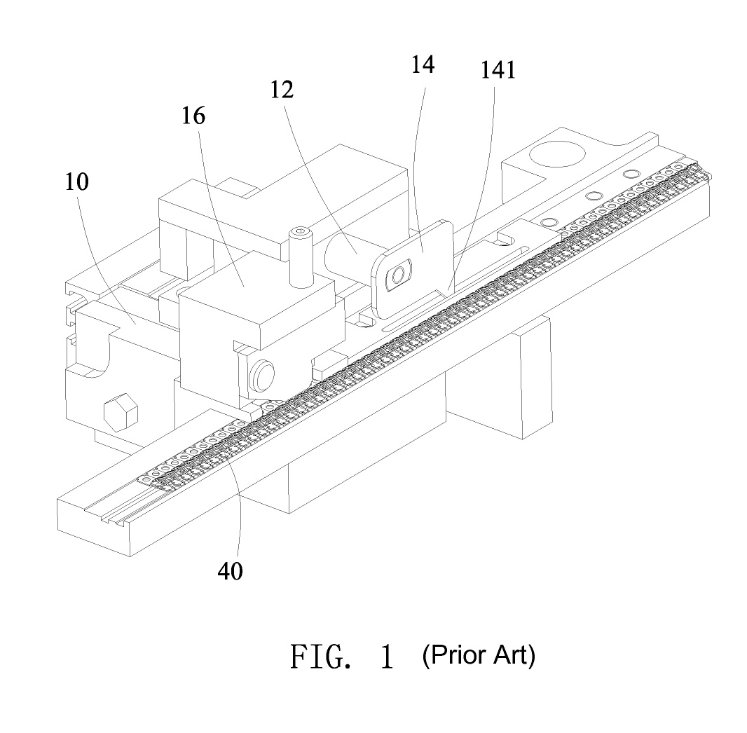

FIG. 2 shows a structure diagram of an embodiment of a transferring mechanism of contact test with a raw material band of terminals according to the present invention.

FIG. 3 shows an enlarged diagram of a portion V shown in FIG. 2.

FIG. 4 shows a structure diagram of a transferring mechanism of contact test shown in FIG. 2 of the present invention, which is applied in a terminal contact tester.

### DETAILED DESCRIPTION OF THE INVENTION

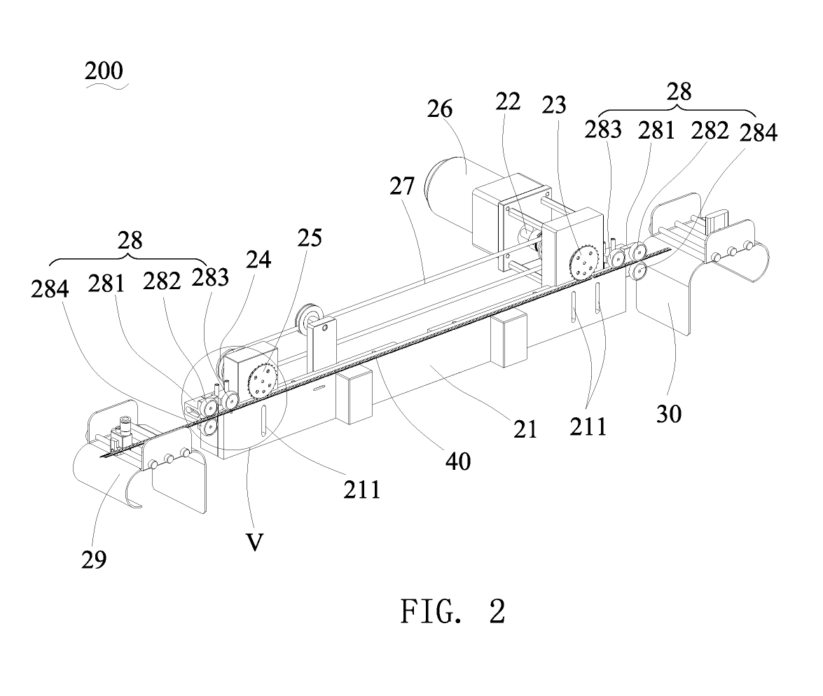

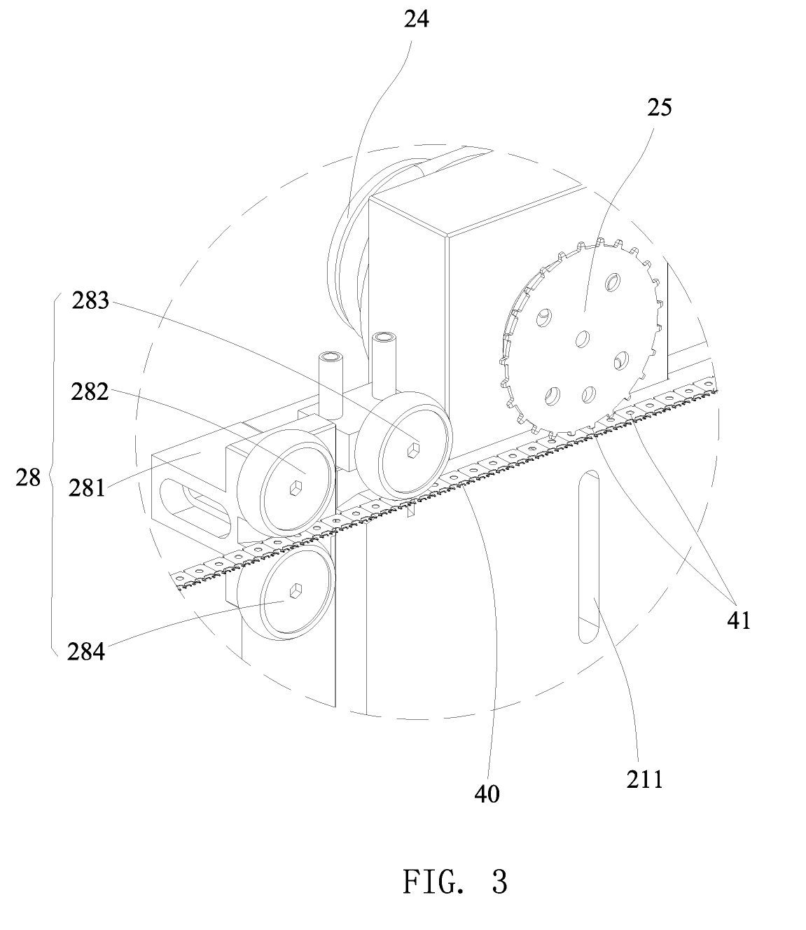

Please refer to FIG. 2 and FIG. 3. The transferring mechanism of contact test 200 according to the present invention is applied to transfer a raw material band of terminals 40 for a contact test of fan-shaped band of terminals. The raw material band of terminals 40 has holes 41 arranged along the terminals in a row.

The transferring mechanism of contact test 200 comprises a main body 21, a driving shaft 22, a driving gear 23 connected with the driving shaft 22, a driven shaft 24, a driven gear 25 connected with the driven shaft 24, a transmission element 26, a belt 27, two guiding apparatuses 28, a charge port 29 for charging the raw material band of terminals 40 and a discharge port 30 for discharging the raw material band of terminals 40. The main body 21 is long shaped and with two ends. The driving shaft 22 and the driving gear 23 are positioned at one end of the main body 21. The driven shaft 24 and the driven gear 25 are positioned at the other end of the main body 21. In this embodiment, the transmission element 26 is a motor and connects to the driving shaft 22 to rotate the driving shaft 22 and the driving gear 23. By the belt 27, the driving shaft 22 rotates the driven shaft 24 and the driven gear 25. The driving gear 23 and the driven gear 25 are both ratchets. The thorn teeth of the driving gear 23 and the driven gear 25 match with the holes 41 of the raw material band of terminals 40 (As shown in FIG. 3). The charge port 29 for charging the raw material band of terminals 40 is close to the driven gear 25. The discharge port 30 for discharging the raw material band of terminals 40 is close to the driving gear 23. The two guiding apparatuses 28 are located between the charging port 29 and the driven gear 25 and between the discharge port 30 and the driving gear 23 respectively. The two guiding apparatuses 28 are fixedly installed on the main body 21.

Specifically, the guiding apparatus 28 comprises a pulley dock 281, a first idler pulley 282, a second idler pulley 283 and a third idler pulley 284. The pulley dock 281 is installed on the main body 21. The first idler pulley 282, the second idler pulley 283 and the third idler pulley 284 are installed on the pulley dock 281. The first idler pulley 282 and the second idler pulley 283 are arranged at one side of the raw material band of terminals 40. The third idler pulley 284 is arranged at the other side of the raw material band of terminals 40 and aligned to the first idler pulley 282. There is a gap, which is adjustable formed between the first idler pulley 282 and the third idler pulley 284. Meanwhile, the position (height) of the second idler pulley 283 relative to the main body 21 is also adjustable for transferring the raw material band of terminals 40 with different thicknesses. As the transferring mechanism of contact test 200 transfers the raw material band of terminals 40, the first idler pulley 282 and the third idler pulley 284 guide the transfer way of the raw material band of terminals 40. The second idler pulley 283 presses the raw material band of terminals 40 to prevent occurrence of an arching of the raw material band of terminals 40, which might happen during the transfer and affect the accuracy of the contact test.

The main body 21 further comprises adjusting slots 211, located under the driving gear 23 and the driven gear 25 respectively. The adjusting slots 211 can be utilized to adjust heights of the driving gear 23 and the driven gear 25 installed on the main body 21 for properly transferring the raw material band of terminals 40 with different thicknesses.

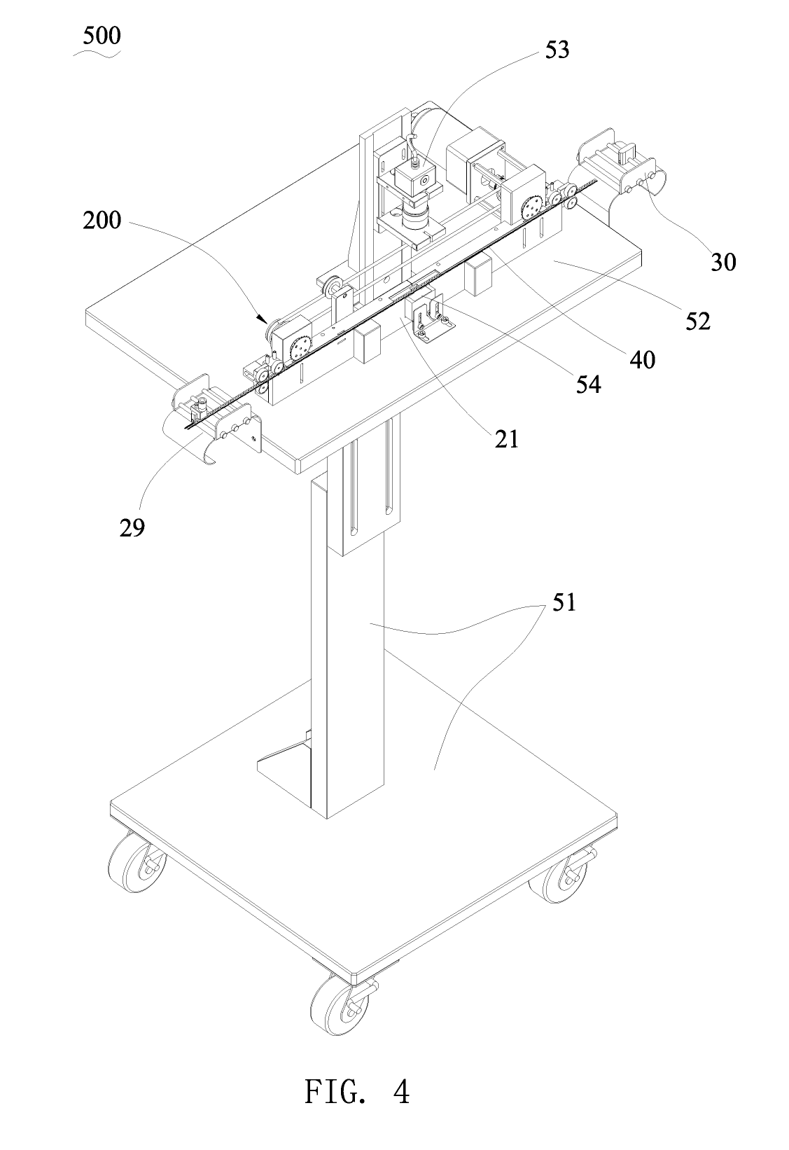

Please refer to FIG. 4, which shows a structure diagram of a transferring mechanism of contact test 200 of the present invention, applied in a terminal contact tester 500. The terminal contact tester 500 comprises a supporting stand 51, a test platform 52, a test device 53, a test zone 54 and a transferring mechanism of contact test 200 of the present invention. The supporting stand 51 stands through the test platform 52. The test device 53 is set up on the test platform 52 and aside the supporting stand 51.

Specifically, the transferring mechanism of contact test 200 is fixedly installed on the test platform 52. The test device 53 is set up between the driving gear 23 and the driven gear 25. There is the test zone 54 located on the main body 21 to be in accordance with the test device 53. The charge port 29 for charging the raw material band of terminals 40 and the discharge port 30 for discharging the raw material band of terminals 40 are located at the two sides of the test platform 52.

As the terminal contact tester 500 is employed for the contact test of the raw material band of terminals 40, first, the raw material band of terminals 40 is manually delivered through the charge port 29, the gap between the first idler pulley 282 and the third idler pulley 284, the second idler pulley 283 and the driven gear 25 in sequence. Then, the terminal contact tester 500 can be activated. The transmission element 26 drives and rotates the driving shaft 22 and the driving gear 23. The driving shaft 22 drives and rotates the driven shaft 24 and the driven gear 25 by the belt 27. Accordingly, the driven gear 25 is synchronously driven and rotated with the driving gear 23. As the driven gear 25 is rotated, hooking the raw material band of terminals 40 is proceeded (The thorn teeth of the driven gear 25 lock the holes 41 of the raw material band of terminals 40). Then, the driven gear 25 transfers the hooked raw material band of terminals 40 toward the test zone 54 for the contact test constantly. After the contact tests of the raw material band of terminals 40 are done, the raw material band of terminals 40 is discharged through the discharge port 30 and then conveyed to the next fabrication line. During the aforesaid contact test process, the property of the intermittent movement of the ratchets is fully utilized for transferring the raw material band of terminals 40 because the driving gear 23 and the driven gear 25 are both ratchets. Therefore, the contact test process of the test device 53 can be coordinated and completed smoothly by the aforesaid intermittent movement and transfer.

As aforementioned, the driving gear 23 and the driven gear 25 of the transferring mechanism of contact test 200 are both ratchets. The thorn teeth of the driving gear 23 and the driven gear 25 match with the holes 41 of the raw material band of terminals 40. During the aforesaid transfer of the raw material band of terminals 40, the property of the ratchets is fully utilized for the aforesaid transfer, accordingly, the transfer speed of the transferring mechanism of contact test 200 is high; the transfer location of the transferring mechanism of contact test 200 can be exact; and the transfer structure of the transferring mechanism of contact test 200 is simple. Meanwhile, the arching of the raw material band of terminals can be effectively prevented and therefore the accuracy of the contact test can be guaranteed.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A transferring mechanism of contact test, applied to transfer a raw material band of terminals for a contact test of fan-shaped band of terminals, the raw material band of terminals having holes arranged along terminals, the transferring mechanism of contact test comprising:
a main body, being long with two ends;
a driving shaft;
a driving gear, connected with the driving shaft and positioned at one end of the main body with the driving shaft;
a driven shaft;
a driven gear, connected with the driven shaft and positioned at the other end of the main body with the driven shaft; and
a transmission element, connecting to the driving shaft to rotate the driving shaft and the driving gear and the driving shaft rotates the driven shaft and the driven gear by a belt, wherein the driving gear and the driven gear are ratchets and the thorn teeth thereof match with holes of the raw material band of terminals.

2. The transferring mechanism of contact test of claim 1, further comprising a charge port and a discharge port for charging and discharging the raw material band of terminals, wherein the charging port is close to the driven gear and the discharge port is close to the driving gear.

3. The transferring mechanism of contact test of claim 2, further comprising two guiding apparatuses, which one is located between the charging port and the driven gear the other is located between the discharge port and the driving gear, wherein the two guiding apparatuses are fixedly installed on the main body.

4. The transferring mechanism of contact test of claim 3, wherein each of the guiding apparatuses further comprises a pulley dock, a first idler pulley, a second idler pulley and a third idler pulley, wherein the pulley dock is installed on the main body and the first idler pulley, the second idler pulley, the third idler pulley are installed on the pulley dock, wherein the first idler pulley, the second idler pulley are arranged at one side of the raw material band of terminals and the third idler pulley is arranged at the other side of the raw material band of terminals and aligned to the first idler pulley.

5. The transferring mechanism of contact test of claim 1, wherein the main body further comprises adjusting slots, located under the driving gear and the driven gear respectively for adjusting positioned heights of the driving gear and the driven gear.
